(19) United States
(12) Patent Application Publication
(10) Pub. No.: US 2004/0217346 A1
(43) Pub. Date: Nov. 4, 2004

(54) Method of deposting a dielectric film

(76) Inventors: Liam Joseph Cunnane, Portland, OR (US); Knut Beekmann, Weston-in-Gordano (GB)

Correspondence Address: VOLENTINE FRANCOS, PLLC, ONE FREEDOM SQUARE, 11951 FREEDOM DRIVE SUITE 1260, RESTON, VA, 20190, US

(21) Appl. No.: 10/484,888

(22) PCT Filed: Jul. 15, 2002
(86) PCT No.: PCT/GB02/03209

(30) Foreign Application Priority Data
Jul. 28, 2001 (GB) 0118417.5

(51) Int. Cl. H01L 35/24

(52) U.S. Cl. 257/40; 438/758

(57) ABSTRACT

This invention relates to a method of depositing a dielectric film on a substrate surface having metal lines thereon with at least some spacings between 4 μm and 20 μm including reacting at least one silane containing gas and at least one of oxygen or an oxygen containing gas in a chamber to form a film on the surface of the substrate within the chamber wherein the chamber pressure is below 850 mT and wherein spaces between the metal lines are at least substantially filled by the film.

One of the major developments in the manufacture of semi-conductor devices in the last few years has been the production of low dielectric constant (k) films and in one form or architecture these films are utilised to fill the gaps between deposited metal lines to receive a subsequent deposition of a conformal plasma capping silicon oxide, which is then chemically mechanically polished to provide a smooth global planar surface for the reception of the next level of wiring.

One film which is particularly successful in this connection is produced by reacting a mixture of silane and methyl silane with flash evaporated hydrogen peroxide onto a metallised semi-conductor wafer sitting on a cooled platen. Currently this deposition takes place at a “standard” set of conditions which are as follows:

| | |
|---|---|
| Silane | = 20 sccm |
| Methyl silane | = 50 sccm |
| Hydrogen peroxide | = 0.75 g/min |
| Pressure | = 900 mT |
| Platen temperature | = 8° C. |

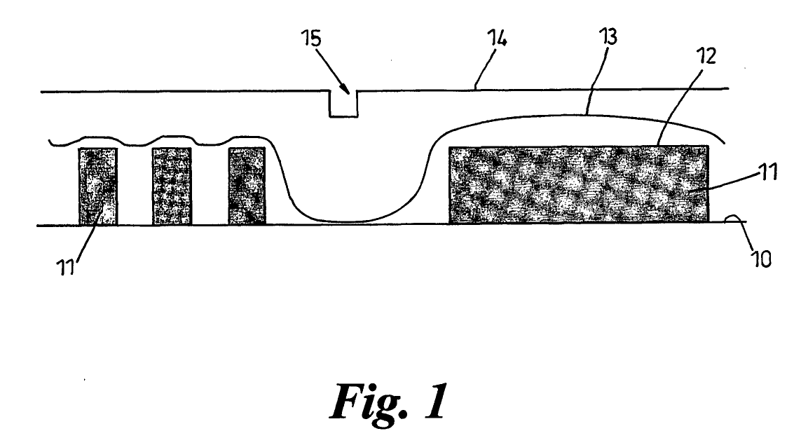

However, it has been found that for some reason the process does not fill certain gap spacings very well and this is illustrated in FIG. 1. As can be seen the substrate 10 carries metal lines 11 which are variably spaced. A low k film 12 has been deposited and in the wider spacing of 5 μm to 15 μm the filling has been rather poor. This result is surprising as this process is capable of filling very small gaps down to less than 0.1 μm very well. The subsequent conformal capping silicon oxide layer 13 will have substantially the same profile, with the result that, when it is chemically mechanically polished back to a flat surface 14, a channel 15 can be present it its surface. If left the channel will become filled with metal during the next metallisation step and there is a substantial risk that short circuits will result.

The present invention consists in a method of depositing a dielectric film on a substrate surface having metal lines thereon with at least some spacings between 4 μm and 20 μm including reacting at least one silane containing gas and at least one of an oxygen or an oxygen containing gas in a chamber to form a film on the surface of the substrate within the chamber, wherein the chamber pressure is below 850 mT and wherein spaces between the metal lines are at least substantially filled by the film.

Surprisingly it has been found that a relatively small reduction in pressure creates a significant reduction in the variation in levels in the deposited film (otherwise known as the step height) for these intermediate line gaps of 5 μm to 15 μm with no significant improvement being noted for the sub micron or very large line gaps. It is particularly preferred that the pressure is 800 mT or below.

It has further been determined that an increase in the platen temperature can improve the step height, although with somewhat bigger gaps between the metal lines, such an increase is detrimental. A temperature range of 2° C. to 15° C. is preferred.

Where the gasses being reacted are silane, methyl silane and hydrogen peroxide, then a further step height reduction can be achieved by proportionally increasing the flow rate of the gasses from the standard arrangement mentioned above. Typically a ten per cent increase in this flow rate is beneficial.

The invention also includes a semi-conductor device incorporating such a deposited film.

Although the invention has been defined above it is to be understood it includes any inventive combination of the features set out above or in the following description.

The invention may be performed in various ways as specific embodiments will now be described with reference to the accompanying drawings, in which:

FIG. 1 is a schematic cross section showing a profile through a prior art semi-conductor device illustrating the problem to be solved by the invention;

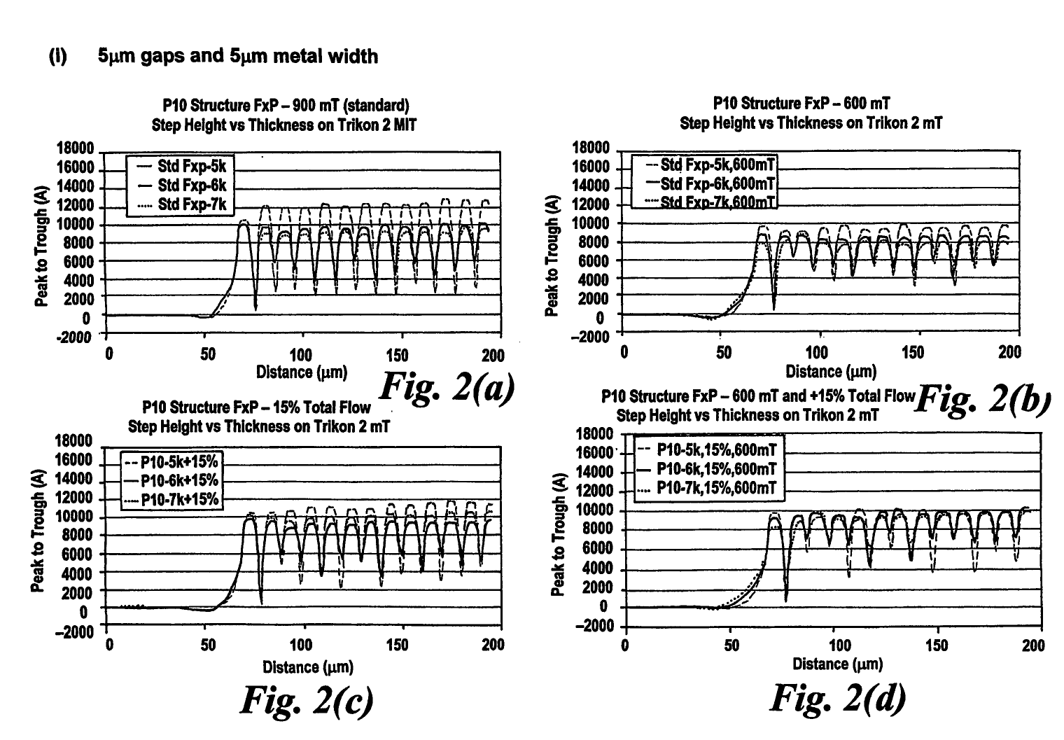

FIGS. 2a-d illustrate respectively the standard process, a reduced pressure process, an increased flow process and a reduced pressure and increased flow process for various thicknesses of film deposited on a surface bearing 5 μm metal lines with 5 μm gaps;

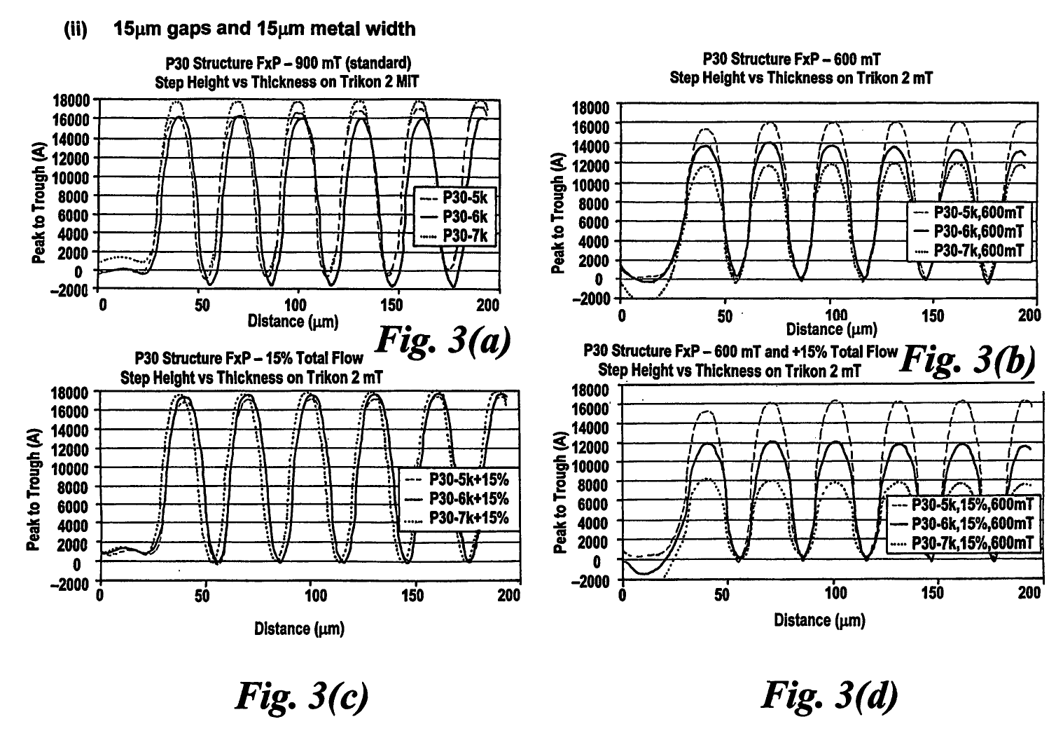

FIGS. 3a-b are the corresponding graphs for 15 μm metal width lines and 15 μm gaps;

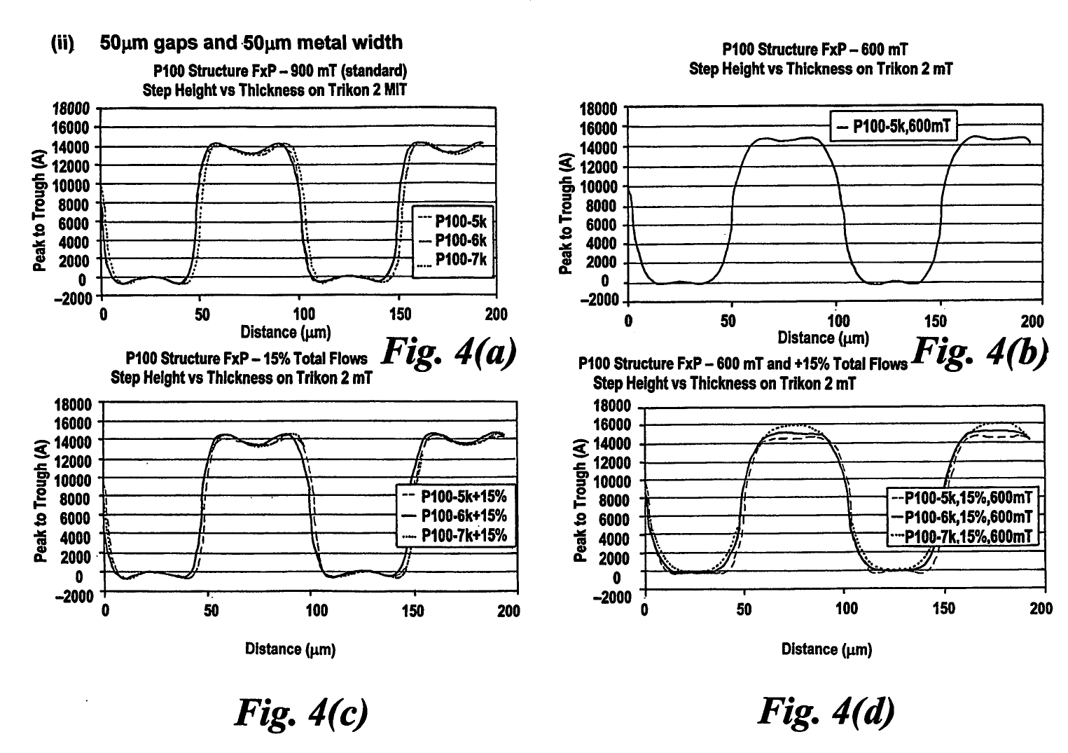

FIGS. 4a-d are the corresponding graphs for 50 μm metal lines with 50 μm gaps;

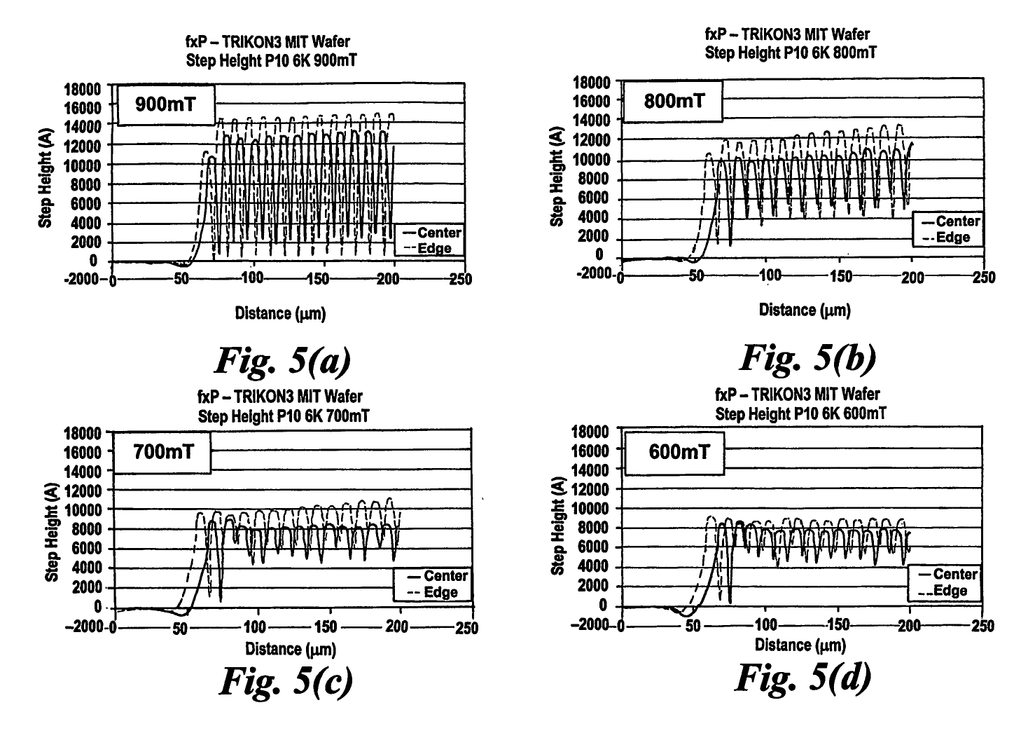

FIGS. 5a-d illustrate the effect of pressure reduction on a 6,000 Å film with 5 μm metal lines and 5 μm gaps;

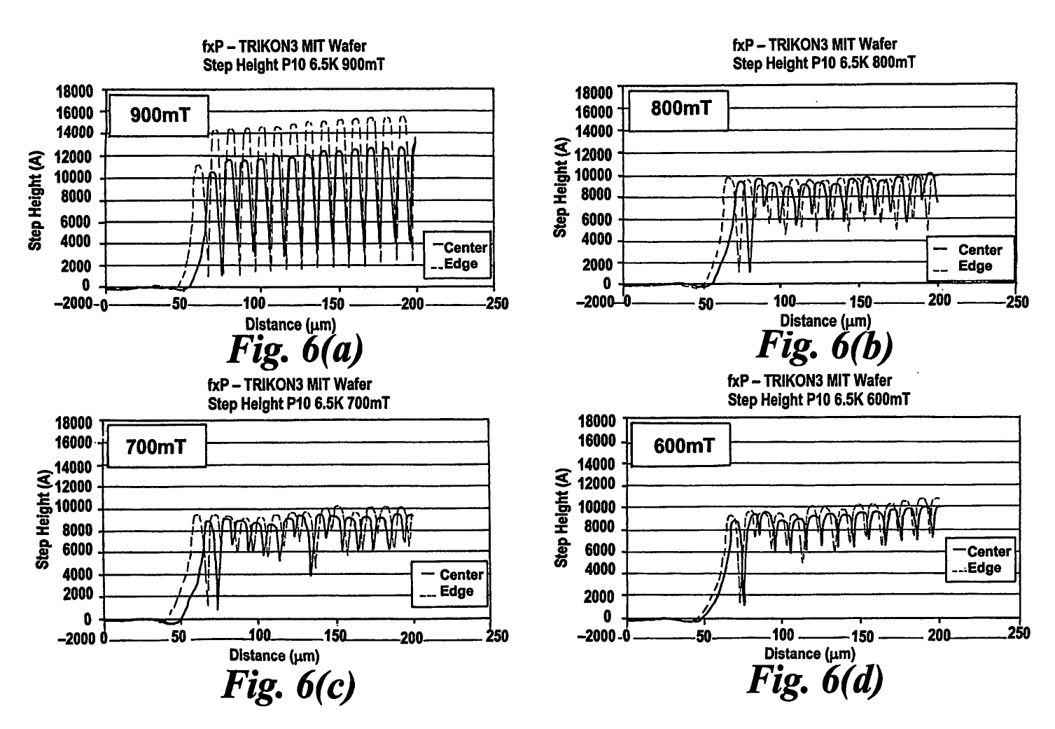

FIGS. 6a-d show the same graphs as FIGS. 5a-d but for a 6,500 Å0 film;

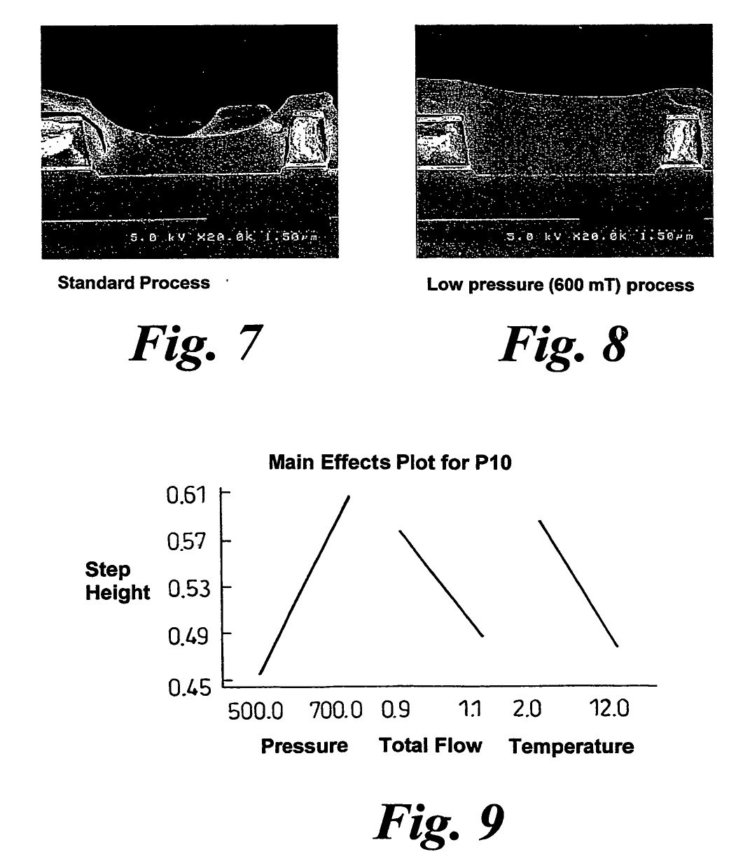

FIG. 7 is an SEM of a cleaved substrate on which film has been deposited using the standard process;

FIG. 8 is a corresponding SEM utilising the process of the invention with a pressure of 600 MT; and

FIG. 9 is a plot of the results of the various experiments illustrating the comparative effects of changes in pressure, flow rate and temperature.

As has been explained above, the peak to trough or step height measurement on a sample, is an indication of how well and uniformly gaps between metal lines have been filled. In FIG. 2-4 these measurements have been taken in respect of films which are 500, 600 and 700 nm thick. These films are designated respectively 5k, 6k and 7k on the drawings. In FIG. 2a the standard process has been run and it will be seen that the variation in step height is significant for all films, the smaller the step height. In FIG. 2b the pressure has been reduced to 600 mT and there is a significant improvement in step height for all thicknesses and the variation between the respective traces is also greatly reduced. In FIG. 3b the standard pressure is used and the flow rate increased and again there is an improvement in the step height, but it is not as consistent as occurs with pressure reduction. In FIG. 2d reduced pressure and flow rate are used together and it will be seen that the graph is rather similar to that for reduced pressure only.

Thus in summary there is an improved step height reduction with:

1. Lower pressure and higher flows;

2. Lower pressure;

3. Thicker films.

In FIG. 3a-d a similar analysis can take place for the situation where the gaps are increased to 15 μm. Here it can be seen that increased flow rate on its own does little, but it is significantly more effective when taken in combination with reduced pressure. Similarly film thickness on its own does not seem to make the same level of difference as with the smaller gaps, but taken in combination with reduced pressure and increased flow rate, significant improvements can be achieved.

In FIGS. 4a-d, it can be seen that none of these parameters make any difference whatsoever.

Thus it has been found that, surprisingly, for certain gap widths only, a significant improvement in step height can be achieved by reducing the pressure, increasing the flow rate and depositing a relatively thick film.

FIGS. 6a-d and 7a-d illustrate the significance of the pressure change in particular for 600 nm and 650 nm films when dealing with 5 μm gaps. It will be seen that there is a significant transition between running the process at 900 mT and 800 mT and that further smaller benefits can be achieved particularly in forms of uniformity, with further pressure reductions. It will be noted that it these graphs the step height is measured both at the centre and at the edge.

These results are essentially summarised in FIG. 9 in respect of 5 μm gaps. These show that step height is reduced by reducing pressure, increasing flow and increasing the temperature. Interestingly an increase in temperature for 50 μm gaps is detrimental.

Turning to FIGS. 7 and 8 the dramatic improvement in step height between the standard process and a reduced pressure process can readily be seen.

We claim:

1: A method of depositing a dielectric film on a substrate surface having metal lines thereon with at least some spacings between 4 μm and 20 μm including reacting at least one silane containing gas and at least one of oxygen or an oxygen containing gas in a chamber to form a film on the surface of the substrate within the chamber wherein the chamber pressure is below 850 mT and wherein spaces between metal lines are at least substantially filled by the film.

2: A method as claimed in claim 1 wherein the pressure is 800 mT or below.

3: A method as claimed in claim 1 wherein the substrate is placed on a platen and the platen temperature is between 2° C. and 15° C.

4: A method as claimed in claim 1 wherein the silicon containing gas is a mixture of silane and methyl silane.

5: A method as claimed in claim 1 wherein the silicon containing gas is a mixture of silane and methyl silane and the flow rate of silane is >20 sccm and the flow rate of methyl silane is >50 sccm.

6: A method as claimed in claim 1 wherein the oxygen containing gas is hydrogen peroxide.

7: A method as claimed in claim 1 wherein the hydrogen peroxide is flash evaporated in the chamber and the flow rate of hydrogen peroxide is >0.75 g/min.

8: A method as claimed in claim 1 wherein the deposited film has a thickness >500 nm.

9: A semi-conductor device having a planarisation layer deposited by the method of claim 1.
